(19) United States
(12) Patent Application Publication
(10) Pub. No.: US 2021/0403720 A1
(43) Pub. Date: Dec. 30, 2021

(54) Cover and/or Filling Material, Optoelectronic Device, Method for Manufacturing an Optoelectronic Device and Method for Manufacturing a Cover and/or Filling Material

(71) Applicant: OSRAM Opto Semiconductors GmbH, Regensburg (DE)

(72) Inventors: Ivar Tangring, Regensburg (DE); Kathy Schmidtke, Mainburg (DE)

(21) Appl. No.: 17/290,638

(22) PCT Filed: Nov. 6, 2019
(86) PCT No.: PCT/EP2019/080331

§ 371 Date: Apr. 30, 2021

(30) Foreign Application Priority Data
Nov. 6, 2018 (DE) 10 2018 127 691.5

(51) Int. Cl. C09C 1/36; C08K 3/22; C08J 3/12; H01L 33/56

(52) U.S. Cl. CPC C09C 1/3661; C08K 3/22; C09C 1/3684; C09C 1/3692; C08K 7/18; H01L 33/56; C08K 2003/2241; C08K 2201/005; C08J 3/12

(57) ABSTRACT

In an embodiment a granular cover and/or filling material includes a plurality of particles, wherein each particle consists of a matrix material in which at least one filler particle is incorporated, and wherein each filler particle comprises titanium dioxide and a coating material.

This patent application is a national phase filing under section 371 of PCT/EP2019/080331, filed Nov. 6, 2019, which claims the priority of German patent application 10 2018 127 691.5, filed Nov. 6, 2018, each of which is incorporated herein by reference in its entirety.

### TECHNICAL FIELD

The present invention relates to a granular, in particular powder-like, cover and/or filling material, an optoelectronic device comprising a material layer with a cover and/or filling material, a method for manufacturing an optoelectronic device using a cover and/or filling material and a method for manufacturing a granular cover and/or filling material.

### BACKGROUND

Optoelectronic devices are known from the prior art which comprise a carrier, in particular in the form of a lead frame, wherein at least one optoelectronic component, such as an LED (for Light Emitting Diode), is arranged on a surface of the carrier.

In such an optoelectronic device, a material layer may comprise white silicone. This material layer may, for example, be formed circumferentially around the optoelectronic component on the carrier without covering the light-emitting or light-detecting surface of the optoelectronic component. In this case, the white silicone layer usually consists of cured silicone to which particles of titanium dioxide have been added before curing when it is still flowable. However, the flowable white silicone, for example when titanium dioxide particles with an average particle size of Dv50=170 nm are used, already exhibits high viscosity even at a concentration of only 13 percent by volume. This can be undesirable for some applications.

### SUMMARY

Embodiments provide a possibility of accommodating a higher percentage by volume of small filler particles, such as particles of titanium dioxide, in a layer of material, such as silicone, for example in an optoelectronic device, without a high viscosity of the receiving layer of material having a particularly obstructive effect.

A granular, in particular powder-like, cover and/or filling material comprises a plurality of particles, each consisting of a matrix material in which at least one filler particle is incorporated.

The filler particles can, for example, be particles of titanium dioxide which are incorporated in the matrix material. The matrix material is provided in the form of granules or powder and is thus present in the form of a plurality of particles. These particles can be incorporated into a flowable material layer formed, for example, on the carrier of an optoelectronic device. Subsequently, this flowable material layer can be cured and thus permanently arranged or formed on the optoelectronic device. In this way, a significantly higher volume concentration of filler material can be achieved in the material layer without this leading to major problems in connection with a high viscosity of the receptive flowable material layer.

The matrix material can be a synthetic polymer, such as polysiloxane, which is also known as polyorganosiloxane. Polysiloxanes are also known as silicones. In particular, these are synthetic polymers in which silicon atoms are linked via oxygen atoms.

A respective filler particle may comprise titanium dioxide or be formed from titanium dioxide. The titanium dioxide may be provided with a coating, for example of aluminum oxide or silicon dioxide and/or an organic material. The coating thereby encloses or surrounds the titanium dioxide.

A coated titanium dioxide filler particle can consist of from 50 to nearly 100 weight percent titanium dioxide and the remaining weight percent range consisting of coating material. This means that the titanium dioxide filler particle can consist of up to nearly 100 percent by weight of titanium dioxide, and the remaining portion to 100 percent by weight consists of the coating material. The sum of all components does not exceed 100%.

For example, a titanium dioxide filler particle may comprise of 50 to 99.5 weight percent of titanium dioxide and of 0.5 to 50 weight percent of coating material, with the sum of all components not exceeding 100%. Other exemplary ranges may include:

Titanium dioxide from 50 to 99% by weight, coating material from 1 to 50% by weight,

Titanium dioxide from 50 to 98% by weight, coating material from 2 to 50% by weight,

Titanium dioxide from 60 to 99 percent by weight, coating material from 1 to 40 percent by weight,

Titanium dioxide from 60 to 98 percent by weight, coating material from 2 to 40 percent by weight, and

Titanium dioxide from 50 to 97% by weight, coating material from 3 to 50% by weight.

Intermediate ranges are also possible. The sum of the components does not exceed 100 percent of the total weight.

A respective filler particle can be made of titanium dioxide. Since a batch of titanium dioxide particles is usually not 100% pure, some filler particles may also be made of a material other than titanium dioxide. This is usually unproblematic, for example in the previously outlined use in a material layer of an optoelectronic device. The titanium dioxide filler particles can be coated. This allows them to be better protected from environmental influences. Adhesion can also be improved. For example, aluminum oxide (Al₂O₃), silicon dioxide (SiO₂) or an organic coating can be used as a coating.

The titanium dioxide filler particles can also be coated, in particular deliberately, so that the TiO₂ “cores” do not touch each other when the filling level is very high. For example, the titanium dioxide filler particles may be formed of 82 wt % TiO₂ and 18 wt % of a coating of Al₂O₃ and/or SiO₂. The figure “wt %” stands for percent by weight.

According to another example, the titanium dioxide filler particles may comprise TiO₂ in a range between including 40 wt % and including 80 wt %, preferably between including 50 wt % and including 70 wt %, with the remaining weight fraction falling to the coating, for example of Al₂O₃ and/or SiO₂.

The particles of the granular or powder-like cover and/or filling material may fall below a predetermined maximum size. For example, the maximum size may be at least approximately 1 μm, 2 μm, a few micrometers or a few 10 micrometers, or up to 100 μm. The maximum size can also be in the range from 1 μm to 100 μm, preferably from 1 μm to 75 μm, further preferably from 1 μm to 50 μm and further preferably in the range from 1 μm to 30 μm. The upper and lower range limits can thereby belong to the respective range.

Falling below the predetermined maximum size can be ensured in particular by sieving the particles of the granular or powder-like cover and/or filling material by means of a sieve. The mesh size of the sieve can be selected so that only particles below the predetermined maximum size can pass through the sieve.

By using different sieves, batches of the cover and/or filling material can be manufactured whose particles fall below a respective predetermined, batch-dependent maximum size or whose particles have sizes that lie between a predetermined minimum size and a predetermined maximum size.

The particles of the granular or powder-like cover and/or filling material can be rounded, in particular spherically. The rounding can be achieved in particular by means of a chemical or mechanical process.

The filler particles may comprise a mean particle size Dv50 in the range of 50 nm to 500 nm, preferably in the range of 75 nm to 400 nm, more preferably in the range of 100 nm to 300 nm, still more preferably in the range of 150 nm to 250 nm, still more preferably in the range of 150 nm to 200 nm, and for example of 170 nm. The aforementioned “mean particle size Dv50” is a mean volumetric diameter, with 50% of the particles having a smaller volumetric diameter and 50% of the particles having a larger volumetric diameter. Particle diameters can be determined by means of laser diffraction, for example.

If the filler particles have an average particle size of several hundred nanometers, for example in the range between 150 nm and 250 nm, they are particularly suitable for scattering light in a material layer of an optoelectronic device. By light here can be meant not only light in the visible wavelength range, but also light in the infrared or ultraviolet spectral range.

The matrix material may comprise an optical refractive index which is less than 1.5, preferably less than 1.4, still more preferably less than 1.3. The cover and/or filling material, which consists of a plurality of particles of the matrix material at least partially filled with filler particles, is thus particularly suitable for use in a layer of an optoelectronic device.

The matrix material can be filled with filler particles to a predetermined value of volume percent. The value of volume percent can be in the range of 20 to 50 volume percent, preferably in the range of 30 to 40 volume percent. The value of volume percent can also be at least approximately 30 volume percent or at least approximately 40 volume percent.

The cover and/or filling material can be added to a wall paint, for example a white wall paint. A high opacity of the wall paint can be achieved by the cover and/or filling material. Embodiments of the invention can thus also relate to a wall paint with a cover and/or filling material.

Embodiments of the invention also relates to an optoelectronic device with a carrier, an optoelectronic component, in particular an LED, on the carrier, and at least one material layer, in particular on or next to the optoelectronic component, wherein the material layer can comprise a cover and/or filling material or can be formed from the cover and/or filling material.

In particular, the material layer can be formed from a silicone, in particular a transparent and/or flowable silicone, with the cover and/or filling material incorporated into the silicone. Subsequently, the silicone with the incorporated cover and/or filling material can be cured. The incorporation of the cover and/or filling material into the material of the material layer can take place before the material layer is arranged in the optoelectronic device. The material of the material layer to be formed, mixed with the cover and filling material can thus be applied to an intended area, for example of the carrier, in particular in a dispensing process.

Embodiments of the invention also relate to a method for manufacturing an optoelectronic device having a carrier on which at least one optoelectronic component, in particular an LED, is arranged, wherein the optoelectronic device comprises at least one flowable material layer, for example of silicone, and wherein the method comprises incorporating a cover and/or filling material into the material layer and subsequently curing the flowable material layer with the incorporated cover and/or filling material.

Furthermore, embodiments of the invention relate to a method for manufacturing a granular or powder-like cover and/or filling material, in which a plurality of filler particles, in particular comprising titanium dioxide, is incorporated into a flowable matrix material, in particular a synthetic polymer, such as polyorganosiloxane, the matrix material with the filler particles is cured, the cured matrix material with the filler particles is ground, and particles of the material with the filler particles are selected from the ground material in such a way that the particles fall below a predetermined maximum size and/or exceed a predetermined minimum size.

By means of the method for manufacturing, a batch of cover and/or filling material can thus be produced, for example, in which the plurality of particles falls below the predetermined maximum size and/or exceeds the predetermined minimum size. The maximum size may, for example, be in the range from including 1 μm to including 100 μm. Such a batch of cover and/or filling material is suitable, for example, for use in a material layer in an optoelectronic device.

The particles can be selected from the ground material by means of at least one sieve, the sieve being designed in such a way that only those particles can pass through the sieve which are below the predetermined maximum size. By using several sieves that allow different maximum sizes to pass, different batches of cover and/or filling material with different maximum particle sizes can be realized. In addition, batches can be realized in which the particles exceed a certain minimum size and fall below a certain predetermined maximum size.

The maximum size and/or minimum size can be at least approximately 1 μm, 2 μm, 5 m, 10 μm, 15 μm, 20 μm, 25 μm, 30 μm, 50 μm, 75 μm or 100 μm. Maximum sizes and/or minimum sizes in the range from 1 μm to 100 μm, preferably from 100 μm to 75 μm, further preferably from 100 μm to 50 μm and further preferably from 1 μm to 30 μm are also possible.

The particles of the plurality of particles of the cover and/or filling material can be rounded, for example spherically, in particular by means of a mechanical or chemical process.

The filler particles can have a mean particle size—Gv50—in the range of a few nanometers to a few hundred nanometers. Preferably, the average particle size is in the range of 150 nm to 250 nm, for example about 170 nm.

### BRIEF DESCRIPTION OF THE DRAWINGS

The invention is described in more detail below by way of example with reference to the accompanying figures.

FIG. 1 shows a cross-sectional view of particles of a variant of a cover and/or filling material;

FIG. 2 shows a cross-sectional view of a variant of an optoelectronic device;

FIG. 3 shows a cross-sectional view of a further variant of an optoelectronic device;

FIG. 4 shows a cross-sectional view of yet another variant of an optoelectronic device;

FIG. 5 shows a cross-sectional view of a material layer with particles of a cover and/or filling material;

FIG. 6 shows a cross-sectional view of a further material layer with particles of a cover and/or filling material, the particles having different sizes; and

FIG. 7 show a flow diagram of a variant of a method for manufacturing a granular or powder-like cover and/or filling material.

### DETAILED DESCRIPTION OF ILLUSTRATIVE EMBODIMENTS

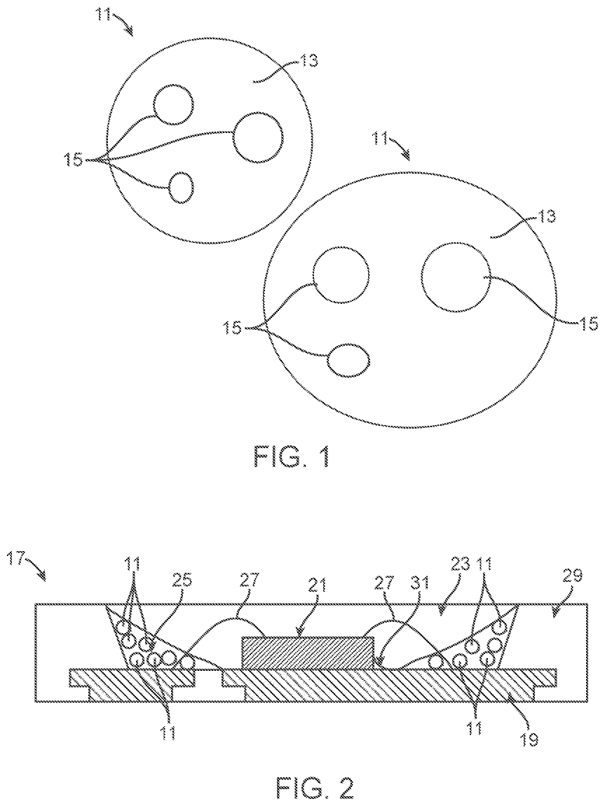

The granular or powder-like cover and/or filling material shown in FIG. 1 comprises a plurality of particles 11, which may be of different sizes. Each particle 11 comprises a matrix material 13 in which one or more small filler particles 15 are incorporated. The matrix material 13 may comprise a synthetic polymer, such as polysiloxane, and the filler particles 15 may comprise, for example, titanium dioxide (TiO₂). In this regard, the titanium dioxide filler particles 15 may comprise a size of several tens or several hundreds of nanometers, for example an average particle size Dv50 of about 170 nm. This allows the titanium dioxide filler particles to function particularly well as scattering bodies for light, for example in an optoelectronic device.

The matrix material 13 may comprise a size of some 10 μm, for example in the range between 1 μm and 30 μm. The large number of particles 11 of a granulate or powder of cover and/or filling material can be below a certain maximum size by sieving the particles 11 with a sieve. The sieve specifies the maximum size below which the particles must fall in order to pass through the sieve.

As shown, the particles 11 and thus in particular the outer periphery of the matrix material 13 may be rounded. This rounding can be realized by means of a mechanical or chemical process.

The matrix material 13 may comprise an optical refractive index that is at least approximately 1.3. Further, the filler particles 15 may occupy a predetermined value of volume percent in the matrix material 13. For example, the value may be in the range between including 30 to including 40 volume percent.

The optoelectronic device 17 shown in FIG. 2 comprises a carrier 19, which may be, for example, a lead frame, in particular a silver-coated copper lead frame. An optoelectronic component 21, such as an LED, is arranged on the carrier 19, which may be a so-called volume emitter. In the case of a volume emitter 21, not only the upper surface can emit light, but also the lateral surfaces which run perpendicular to the upper surface of the carrier 19.

A conversion layer 23 surrounds the optoelectronic component 21, as shown in FIG. 2. The conversion layer 23 forms a flat surface at the top of the device 17, and light can pass out of the device 17 through the surface.

The conversion layer 23 may comprise a conversion material, such as phosphor, by means of which the light emitted from the optoelectronic component 21 can be converted into light of at least one other wavelength. A reflector layer 25 surrounds the conversion layer 23. As shown, the reflector layer 25 is funnel-shaped so that it can act as a reflector for the light converted in the conversion layer 23 in an improved manner and can contribute to improved upward light emission.

Electricity can be supplied to the optoelectronic component 21 via electric lines 27, in the form of bonding wires, which extend from the upper surface of the optoelectronic component 21 to a respective electrical contact point on the carrier 19.

A cover 29—for example white cover—surrounds the optoelectronic device 17, without covering the upper surface of the conversion layer 23. An upward light emission is thus not blocked by the cover 29.

In the optoelectronic device 17, the reflector layer 25 comprises an originally flowable material, such as silicone, which has been cured. A plurality of particles 11 of the cover and/or filling material (cf. FIG. 1) have been incorporated into the still flowable material. The flowable material mixed with the particles 11 may have been applied to the carrier 19 to form the reflector layer 25. Subsequently, the material with the particles 11 of cover and/or filling material incorporated therein may have been cured.

By using the cover and/or filling material consisting of a plurality of particles 11, a respective particle 11 consisting of the matrix material 13 in which one or more filler particles 15 are incorporated, a higher proportion by volume of filler particles 15 can be achieved in the reflector layer 25, in particular in comparison with direct incorporation of filler material, such as titanium dioxide in particular, into flowable silicone. This should be seen in particular against the background that flowable silicone into which a small proportion of titanium dioxide has already been introduced, for example a proportion of less than 20 percent by volume, has such a high viscosity that it is practically difficult to handle. In contrast, at least the same or even a higher volume concentration of filler particles can be achieved—with lower viscosity of the material layer mixed with particles 11—by introducing the particles 11 of the cover and/or filling material into the flowable silicone. A higher concentration of filler particles in the reflector layer 25 can increase the reflectivity of this layer.

If the matrix material 13 of the particles 11 consists of polysiloxane and the filler particles 15 consist of titanium dioxide, a reduced coefficient of thermal linear expansion can also be achieved—compared to a reflector layer 25 made of silicone with titanium dioxide particles directly contained therein. On the one hand, this results from the fact that the matrix material 13 has a lower coefficient of thermal linear expansion than a silicone matrix directly accommodating the titanium dioxide particles. On the other hand, this results from the fact that an at least slight reduction in the coefficient of thermal linear expansion is possible due to the higher possible volume concentration of titanium dioxide particles.

In the case where the matrix comprises an optical refractive index of less than 1.4, this is lower than the refractive index of silicone. Reflectivity is thus increased, especially to a level that would not be achievable with TiO₂ particles added directly to silicone, even if one could increase the concentration of TiO₂ in silicone. For the example or use case of the “wall paint”, a solvent may well be used to add a great deal of titanium dioxide to the liquid wall paint. There, the increased reflectivity would be a decisive advantage, leading to the fact that thinner paint is needed to completely cover a wall.

The particles 11 of the cover and/or filling material according to FIG. 1 are orders of magnitude larger than the embedded filler particles 15, for example of titanium dioxide. During a possible creep process of the silicone of the reflector layer 25, which is still flowable before curing, these larger particles 11 are carried along to a lesser extent or possibly not at all by the creeping silicone. A section 31 of the reflector layer 25 possibly reaching a lateral, light-emitting outer surface of the optoelectronic component 21 thus causes no or at most only slight scattering of the light emerging from the lateral surface of the optoelectronic component 21.

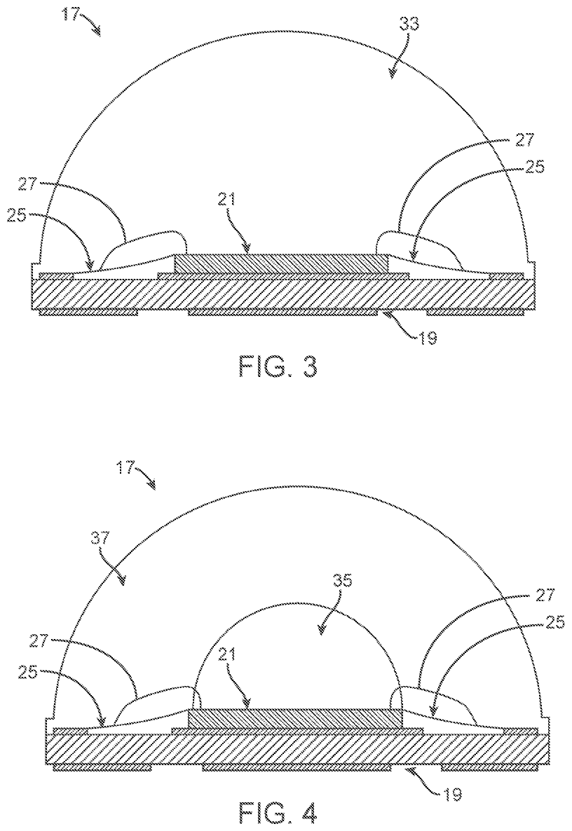

The variant of an optoelectronic device 17 shown in FIG. 3 comprises a carrier 19 with an optoelectronic component 21 arranged thereon, which is in particular a surface emitter, so that light is emitted only via the upwardly directed surface of the optoelectronic component 21. The lateral outer surfaces of the optoelectronic component 21, which extend perpendicularly to the upper surface of the carrier 19, are surrounded by a reflector layer 25 which, as previously described with reference to FIG. 2, can in turn be formed from an initially flowable material, such as silicone, to which particles 11 (not shown in FIG. 3) have been added before curing.

Due to the larger particles 11 compared to titanium dioxide, creep of the still flowable silicone onto the upper surface of the optoelectronic component 21 can be avoided. This results, for example, from the fact that larger particle particles 11, for example with a size already in the range between 1 and 5 μm, are too heavy to be drawn through the flowable silicone onto the upper surface of the optoelectronic component 21. In addition, the particles 11 are also larger than the height of the creeping silicone.

By a higher possible concentration of titanium dioxide in the reflector layer 25, a higher reflectivity can be achieved in the reflector layer 25, as previously described with reference to FIG. 2. As further shown in FIG. 3, a lens 33, for example made of silicone, is still formed on the upper surface of the carrier 19, which encloses the optoelectronic component 21 and the upper surface of the carrier 19.

In the variant of an optoelectronic device 17 shown in FIG. 4, a two-part lens is provided. Here, an inner lens 35, for example made of silicone, surrounds the light-emitting upper surface of the optoelectronic component 21, while the outer lens 37, similar to the lens 33, completely encloses the entire upper surface of the carrier 19 with the components lying thereon.

In terms of manufacturing technology, the inner lens 35 is produced before the reflector layer 25 and then the outer lens 37 are formed. During the manufacture of the reflector layer 25, the larger particles 11 in the initially still flowable reflector layer 25, which is formed from silicone mixed with the particles 11, can prevent or at least reduce creep of the not yet cured reflector layer 25 up the surface of the inner lens 35. This can prevent the inner lens 35 from becoming laterally white, thereby avoiding a partial interruption of the outcoupling out of light from the inner lens 35. This results in particular again from the size and mass of the white particles 11 (not shown in FIG. 4) in the reflector layer 25. Upwardly, the creeping silicone forms a narrow tip. The large particles 11 here are too large to be received in the tip. Thus, there is a lack of force to pull the particles 11 up along the surface of the inner lens 35. Also, due to their larger mass, the particles 11 are not as easily pulled up or sediment back down. After the reflector layer 25 has cured, the outer lens 37 is formed.

Further, as previously described, a higher feasible concentration of titanium dioxide in the reflective layer 25 can provide a higher reflectivity of the reflective layer 25 and thus a higher light extraction efficiency from the optoelectronic device 17.

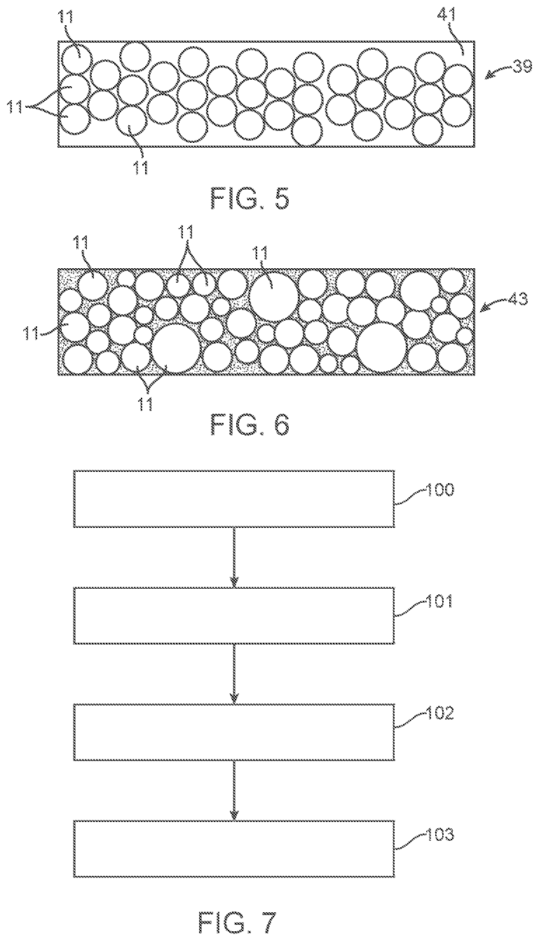

FIG. 5 shows a white silicone layer 39, such as can be used, for example, as a reflector layer 25. The silicone layer 39 comprises cured silicone 41 into which—while it was still in the flowable state—particles 11 of a cover and/or filling material were incorporated. The particles 11 may comprise polysiloxane as matrix material 13 and titanium dioxide as filler particles 15. For example, the amount of titanium dioxide in a particle 11 may be at least approximately 40% by volume. The titanium dioxide filler particles 15 may have an average diameter Dv50 of at least approximately 170 nm. The diameter of the particles 11 may be in the range of 5 to 10 μm. The volume concentration of particles 11 in the flowable silicone may be, for example, 34%. This results in a volume fraction of titanium dioxide filler particles 15 in the silicone layer 39 of 0.4*0.34=0.136, i.e. of 13.6% by volume.

The viscosity of a slurry consisting of the still flowable silicone layer 39 with the particles 11 incorporated therein is significantly smaller than the viscosity of flowable silicone to which about 13.6 volume percent titanium dioxide particles have been added directly. One reason for this can presumably be seen in the fact that in the aforementioned slurry, the particles 11 have a total surface area that is smaller by about a factor in the range between 10 and 25 than the total surface area of the 13.6 volume percent of titanium dioxide particles that are introduced directly into the silicone. The aforementioned slurry therefore offers advantages in processability.

In the white silicone layer 43 shown in cross-section in FIG. 6, particles 11 of different sizes have been incorporated. In addition, titanium dioxide particles were added directly to the flowable silicone before curing. This allows a higher volume concentration of titanium dioxide to be achieved in the silicone layer 43 compared to the silicone layer 39 of FIG. 5, while the viscosity of the slurry comprising the flowable silicone with the added particles 11 of different sizes and titanium dioxide particles added directly to the flowable silicone remains sufficiently low.

For example, a proportion of 5 volume percent of titanium dioxide added directly, a proportion of 20 volume percent of particles 11 with a diameter in the range of 1-5 μm, and a proportion of 20 volume percent of particles 11 with a diameter in the range of 5-10 μm in liquid silicone result in a proportion of about 21 volume percent of titanium dioxide in the liquid silicone and thus also in the silicone layer 43 (0.05+0.2*0.4+0.2*0.4≈0.21). The proportion of titanium dioxide in a particle 11 is thereby approximately 40 volume percent.

A higher volume concentration of titanium dioxide in the silicone layer 43 improves its reflectivity, while the slurry can be easily processed due to its sufficiently low viscosity.

The diameter ranges of the particles 11 mentioned with reference to FIGS. 5 and 6 can be obtained, for example, by appropriate screening of ground material from the particles.

According to the flow diagram of a variant of a method for manufacturing a granular or powder-like cover and/or filling material shown in FIG. 7, the method comprises step 100, in which a plurality of filler particles 15, in particular filler particles 15 of titanium dioxide, are incorporated into a flowable matrix material 13, in particular a synthetic polymer, such as polysiloxane. According to a further step 101, the matrix material 13 added with the filler particles 15 is cured. In a further step 102, the cured matrix material 13 comprising the filler particles 15 is ground. In still another step 103, particles 11 of the matrix material 13 mixed with the filler particles 15 are selected from the ground material obtained in such a way that the particles 11 fall below a predetermined maximum size and/or exceed a predetermined minimum size.

Although the invention has been illustrated and described in detail by means of the preferred embodiment examples, the present invention is not restricted by the disclosed examples and other variations may be derived by the skilled person without exceeding the scope of protection of the invention.

1.-18. (canceled)

19. A granular cover and/or filling material comprising:
a plurality of particles,
wherein each particle consists of a matrix material in which at least one filler particle is incorporated, and
wherein each filler particle comprises titanium dioxide and a coating material.

20. The cover and/or filling material according to claim 19, wherein the matrix material is a synthetic polymer.

21. The cover and/or filling material according to claim 19, wherein each filler particle comprises 50 to approximately 100 weight percent titanium dioxide and a remaining weight percent coating material.

22. The cover and/or filling material according to claim 19,
wherein the particles have a predetermined maximum size, and
wherein the predetermined maximum size is in a range from 1 μm to 100 μm, inclusive.

23. The cover and/or filling material according to claim 19, wherein the particles are spherical.

24. The cover and/or filling material according to claim 19, wherein the filler particles comprise a mean particle size (Dv50) in a range from 50 nm to 500 nm, inclusive.

25. The cover and/or filling material according to claim 19, wherein the matrix material comprises an optical refractive index of less than 1.5.

26. The cover and/or filling material according to claim 19, wherein the matrix material is filled to about 30-40 volume percent with the filler particles.

27. An optoelectronic device comprising:
a carrier;
an optoelectronic component on the carrier; and
at least one material layer on the carrier and/or laterally next to the optoelectronic component,
wherein the material layer comprises the cover and/or filling material according to claim 19.

28. The optoelectronic device according to claim 27, wherein the material layer comprises silicone.

29. A method for manufacturing an optoelectronic device comprising a carrier on which at least one optoelectronic component is arranged, the optoelectronic device having at least one initially flowable material layer, the method comprising:
incorporating the cover and/or filling material according to claim 19 into the flowable material layer; and
subsequently curing the flowable material layer with the incorporated cover and/or filling material,
wherein incorporating the cover and/or filling material into the material layer comprises incorporating the cover and/or filling material before the material layer is formed in the device.

30. A method for manufacturing a granular cover and/or filling material, the method comprising:
incorporating a plurality of filler particles into a flowable matrix material;
curing the matrix material mixed with the filler particles;
grinding the cured matrix material mixed with the filler particles; and
selecting ground filler particles so that the particles have a size below a predetermined maximum size and/or exceed a predetermined minimum size.

31. The method according to claim 30, wherein selecting the ground filler particles comprises sieving the ground filler particles with a sieve, wherein the sieve has openings so that only those particles pass through which are below the predetermined maximum size.

32. The method according to claim 30, wherein different batches of particles are manufactured, the batches differ with respect to the maximum size and/or the minimum size.

33. The method according to claim 30, wherein the maximum size is approximately 100 μm.

34. The method according to claim 30, further comprising rounding the particles by a mechanical or chemical process.

35. The method according to claim 30, wherein the filler particles comprise a mean particle size (Dv50) in a range from 50 nm to 500 nm, inclusive.

36. The method according to claim 30, wherein the matrix material has an optical refractive index which is less than 1.5.

37. The method according to claim 30, wherein the matrix material is filled to 30-40 volume percent with the filler particles.
